(19) United States
(12) Patent Application Publication
(10) Pub. No.: US 2005/0041453 A1
(43) Pub. Date: Feb. 24, 2005

(54) Method and apparatus for reading and writing to solid-state memory

(76) Inventors: Paul W. Brazis, South Elgin, IL (US); Thomas M. Tirpak, Glenview, IL (US); Kin Tsui, Morton Grove, IL (US); Krishna Kalyanasundaram, Elmhurst, IL (US); Daniel R. Gamota, Palatine, IL (US)

Correspondence Address: MOTOROLA, INC., 1303 EAST ALGONQUIN ROAD, IL01/3RD, SCHAUMBURG, IL, 60196, US

(21) Appl. No.: 10/646,231

(22) Filed: Aug. 22, 2003

(51) Int. Cl. G11C 5/06

(52) U.S. Cl. 365/63

(57) ABSTRACT

A method and apparatus for writing to solid-state memory is provided herein. In particular, a controller is provided that monitors operating parameters of each die within the system. In order to enable fast, real-time write operations, feedback from each die is analyzed and compared with a stored set of operating parameters. Based on this comparison, a particular die is chosen for write operations such that system performance is optimized.

### FIELD OF THE INVENTION

The present invention relates generally to solid-state memory and in particular, to a method and apparatus for reading and writing to solid-state memory.

### BACKGROUND OF THE INVENTION

Large-scale (>1 GB) solid-state memory storage is a rapidly expanding market, particularly for multimedia applications. Currently these storage devices have not been successfully applied in usage scenarios where large storage capabilities are needed. For example, personal computers still utilize hard-disk storage as a primary storage mechanism. In order for manufacturers to utilize solid-state memory devices in place of hard-disk storage and for high-reliability applications, the performance of such solid-state memory devices must be improved. One way to improve performance of solid-state memory storage is to increase the performance of read-write operations so that such operations occur more efficiently, and data are well protected from device failures.

### BRIEF DESCRIPTION OF THE DRAWINGS

FIG. 1 is a block diagram of solid-state storage means.

FIG. 2 is a flow chart showing operation of the solid-state storage means of FIG. 1.

FIG. 3 is a flow chart showing a method for detection of non-operational die and the actions of a controller in such a situation.

FIG. 4 is a flow chart for dynamically updating a performance model database.

FIG. 5 is a block diagram of a solid-state storage means in accordance with a second embodiment.

### DETAILED DESCRIPTION OF THE DRAWINGS

To address the need for more efficient read/write operations, and to better protect data written to solid-state memory, a method and apparatus for writing to solid-state memory is provided herein. In particular, a controller is provided that monitors performance characteristics (e.g., temperature, current drain, power consumption, time for read/write/erase operations, etc.) of each die within the system. In order to enable fast, real-time read/write operations, the performance characteristics from each die are measured, analyzed and compared with a stored set of operating parameters. Based on this comparison, a particular die/module is chosen for write operations such that system performance is optimized.

The above-described approach to writing data to solid-state memory provides a practical way to reduce power consumption while improving read-write performance by speed-tuning the selection of memory locations. Additionally, improved device reliability is achieved due to better thermal management.

Notwithstanding the above, the reliable operation of multi-chip modules is achieved even if one or more die perform poorly, or are completely non-functional. In this scenario, reliability and test constraints on each die may be relaxed, resulting in significantly higher overall product yield and correspondingly lower product manufacturing costs. Additionally, field reliability of the product is considerably improved, as the failure of one die during operation may put the system into a recoverable state where the memory array can be field-reconfigured and continue to function. Presently, the failure of a single memory element would result in sudden failure of the entire array and hence unrecoverable loss of all stored data.

The present invention encompasses an apparatus comprising a first solid-state memory die, a second solid-state memory die, and a controller sensing one or more operating parameters for the first and the second solid-state memory die and making intelligent decisions on where to write data, based on the operating parameters.

The present invention additionally encompasses an apparatus comprising a performance model database storing historical operating parameters for a plurality of memory die, an external processor/test controller having current operating parameters for the plurality of memory die as an input along with the historical operating parameters for the plurality of memory die and outputting optimal storage locations, a controller having data as an input and outputting the data destined to be written to a first memory location, and a hardware re-router having the optimal storage locations as an input along with the data, and re-routing the data based on the optimal storage locations.

The present invention additionally encompasses a method for accessing a plurality of solid-state memory die. The method comprises the steps of retrieving operating parameters from the plurality of solid-state memory die, retrieving operating models for the plurality of solid-state memory die, and comparing the operating models with the operating parameters. A memory location is determined based on the comparison and the data are written to the memory location.

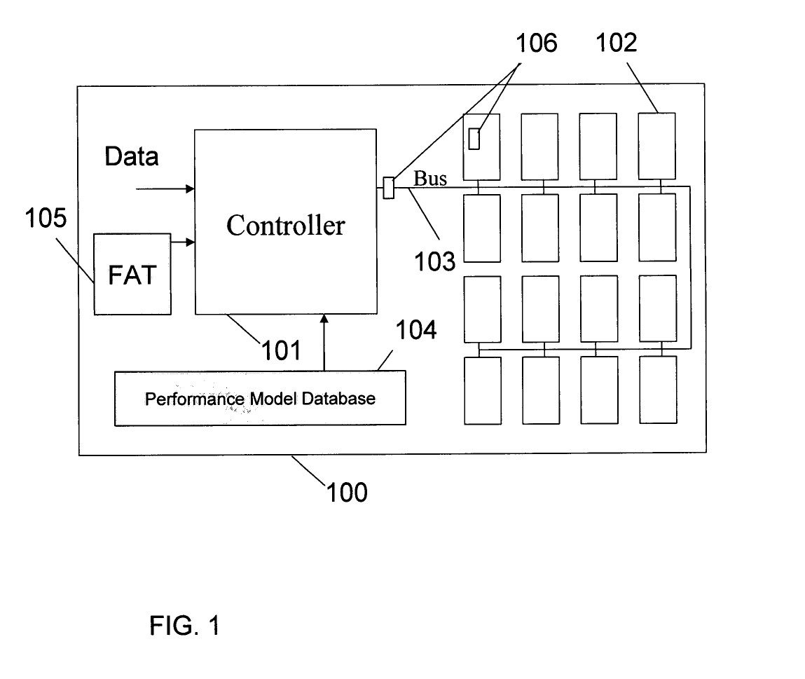

Turning now to the drawings, wherein like numerals designate like components, FIG. 1 is a block diagram of solid-state storage device 100. As shown, device 100 comprises controller 101 having data as an input. Controller 101 is coupled to a plurality of solid-state memory devices 102 via bus 103. Controller 101 is preferably a microprocessor/controller such as a IDE/ATA/PCMCIA/CompactFlash™, SD, MemoryStick™, USB, or other processor capable of managing two or more memory die. Additionally, solid-state memory devices 102 comprise die such as nonvolatile flash memory; however, in alternate embodiments, solid-state memory devices 102 may comprise other memory storage means, such as, but not limited to polymer memory, magnetic random access memory (MRAM), static random access memory (SRAM), dynamic random access memory (DRAM), and Ferroelectric Random Access Memory (FRAM)

It should be noted that each die 102 includes means 106 for sensing its operating parameters and feeding this information back to controller 101. For example, each die 102 may comprise on-board sensors 106 to determine temperature, current draw, access times (read/write/erase times), etc. and an ability to feed this information back to controller 101. Alternatively, external sensors 106 may be coupled to each die 102 in order to determine environmental parameters. Such sensors include, but are not limited to, diode or resistive temperature sensors, thermocouples, and ammeters.

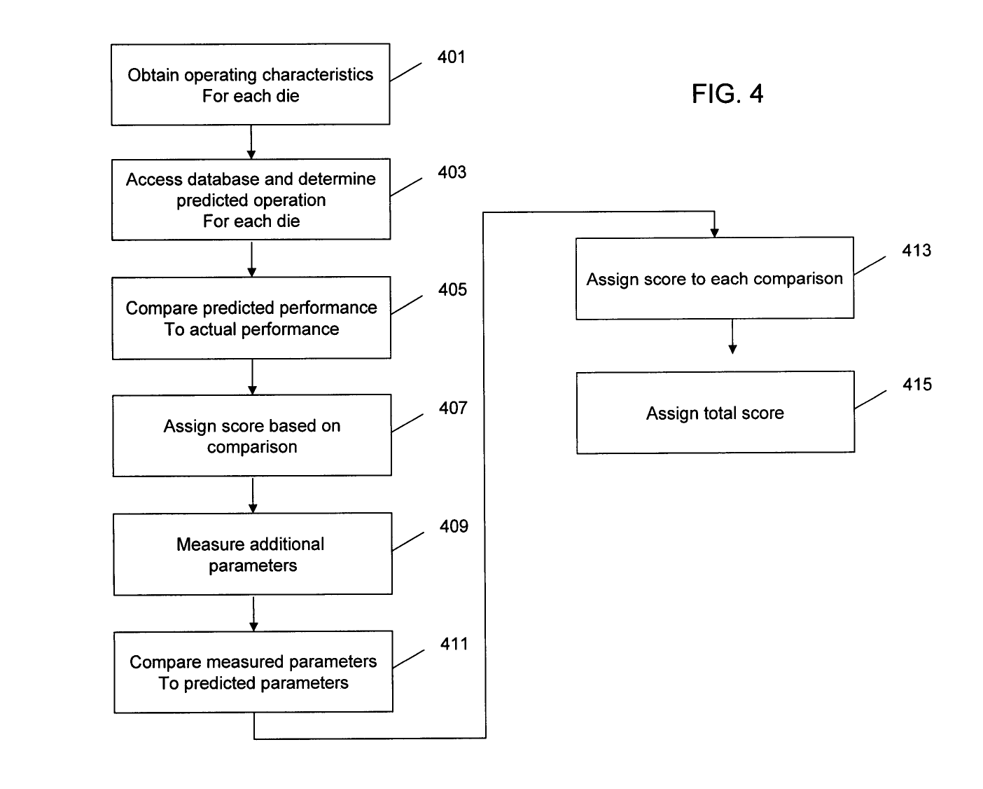

Continuing, bus 103 comprises power supply, chip enable, data and control interconnects, while File Access Table (FAT) 105 comprises a standard FAT as known in the art to store available memory locations within devices 102. Finally, database 104 comprises a database of known performance or operating models for the various die 102. These models are preferably different for each die 102 and are made available to database 104 initially when the system is manufactured or otherwise initialized for use, e.g., during the product “burn-in” tests or a process similar to a “disk format”, where memory die are preprogrammed for compatibility with standard operating systems (e.g., Microsoft Windows, UNIX, etc.). As depicted in FIG. 4, the models can be subsequently adjusted by controller 101 as system performance changes over time, using feedback from each die 102. For example, during manufacture of die 102, the manufacturer may monitor and record such things as current draw, power consumption, temperature, write times, etc. and provide this information for each die. These characteristics may change over time.

During operation, controller 101 dynamically optimizes its read-write operations based on a set of performance models stored in database 104. This is accomplished via each memory module 102 utilizing environmental sensors 106 to determine operating characteristics of each die/module, and continuously feeding back (via bus 103) operating characteristics such as the temperature of the module, the current drain and/or power consumption, etc.

When a user requests that data be stored to memory, controller 101 queries File Access Table (FAT) 105 to obtain a list of available memory locations within the various die. Controller 101 then eliminates any locations that are not desirable based on recent read-write cycles. This may involve a short-term memory of the most recent locations for read-write operations. Once controller 101 has a list of candidate available (free) memory locations, it queries performance models available in database 104 to determine a performance “score” for each memory location. For example, a score may be a function of the current at a particular memory die number and address as compared with historic values. Based on the performance model scores and the inherent trade-offs between performance, temperate, and current (or power), the best memory die and/or location is selected; and the data are written to the location, and FAT 105 is updated accordingly. Note that in some embodiments FAT 105 and controller 101 may be integrated into a single element, or FAT 105 information may be encoded within memory die 102.

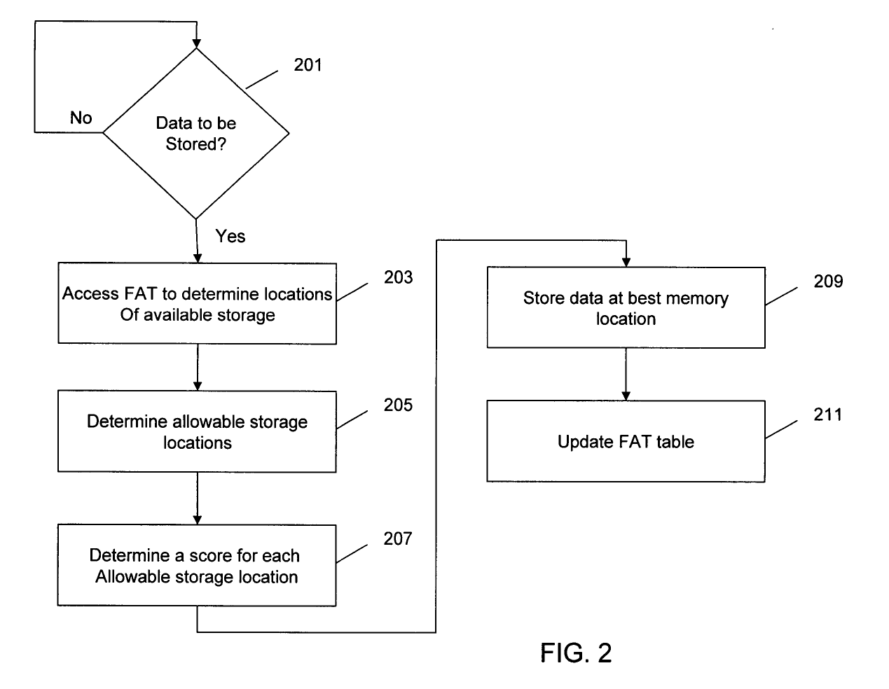

FIG. 2 is a flow chart showing operation of solid-state storage means 100 of FIG. 1. The logic flow begins at step 201 where controller 101 determines if data need to be stored. If, at step 201, data do not need to be stored, the logic flow simply returns to step 201, however, if at step 201 it is determine that data need to be stored, then the logic flow continues to step 203 where FAT 105 is accessed to determine a list of memory locations on die 102 that are available for storage. At step 205, controller 101 then eliminates any locations that are not desirable based on recent read-write cycles, and at step 207 a performance score for each available storage location is determined. As discussed above, the performance score (described in detail below) is obtained by comparing the current environmental parameters of each die to stored information regarding the “normal” performance of each die. Finally, the data are stored at the location with the best “score” (step 209), and FAT table 105 is updated accordingly (step 211).

As discussed above, storing data in locations (die) having the best “score”, provides a practical and computationally efficient way to reduce power consumption while improving read-write performance by speed-tuning the selection of memory locations. Additionally, improved device reliability is achieved due to better thermal management and allows for data to be removed from suspect devices and more securely stored on devices that exhibit normal operation.

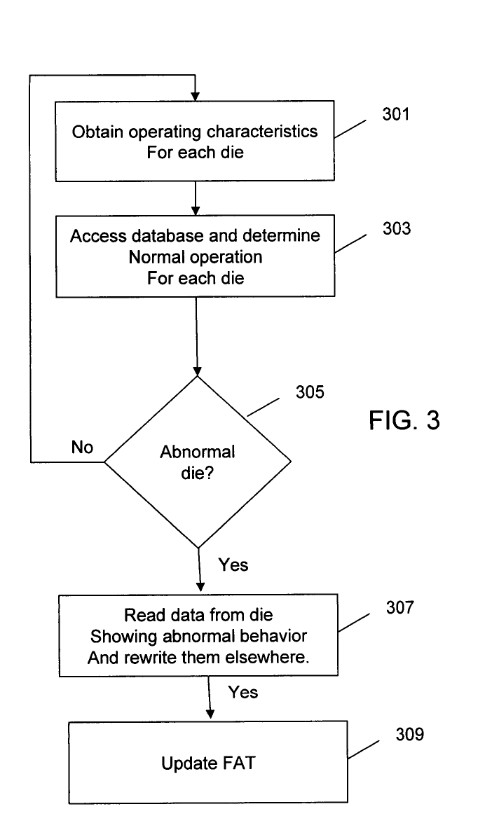

FIG. 3 is a flow chart showing operation of the solid-state storage means of FIG. 1 during situations where data are copied from suspect devices and securely re-written to devices that exhibit normal operation characteristics. The logic flow begins at step 301, where environmental parameters are obtained by controller 101 for each die 102. At step 303, a database 104 is accessed to determine normal operating parameters for each die. At step 305 it is determined if any die exhibits abnormal behavior by comparing the measured operating parameters with the stored parameters. For example, behavior of a specific die may be identified as abnormal if an operating parameter for that die varies by more than X% (e.g., 10%) from historical values.

If, at step 305 it is determined that no die exhibits abnormal behavior, then the logic flow simply returns to step 301, otherwise, the logic flow continues to step 307, where data are removed from the die showing abnormal behavior, and rewritten to a die showing normal behavior. Finally, at step 309, FAT table 105 is updated. As is evident, data may be removed from abnormal die and re-written to the locations selected according to the procedure described above with reference to FIG. 2. In other words, data may be rewritten to those die having a best “score”.

Determining a module/die “score”

A first scoring method is used to simply score candidate storage positions as either good or bad. This method relies primarily on the detection of non-functional die. Memory locations associated with any such non-functional die are removed from the controller's list of candidate locations for the pending write operation (i.e., scored as bad). The specification of non-functional status may be done explicitly, i.e., as a “status flag” for each die. During the initial manufacture of the solid-state memory system, all “status flags” would be set to “good” for each good die. Following the occurrence of one or more unsuccessful read/write operations for a given die, the status flag would be set to “bad”. Subsequently, the controller would no longer consider any locations on this die for future write operations. Memory locations being considered for write operations by the controller, are assigned a score of zero (0) if the status flag is “bad” for the die containing this memory location. Thus, the controller would never select such locations with a score of zero from the rank-ordered list of candidate memory locations.

A second embodiment of the scoring method includes the check of specific locations on each die and utilizing the performance models stored in the performance model database to determine a score. This is illustrated in FIG. 4, which shows a flow chart detailing operation of scoring in this manner. The logic flow begins at step 401 where a first characteristic (e.g., the thermal performance of the die) is estimated as a function of the die number and the memory location. Predicted performance is obtained at step 403 using the model contained in the performance model database.

In a first embodiment, database 104 comprises a database storing the coefficients of a linear prediction model for the various operating parameters, while in a second embodiment a database stores weights and node-interconnect lists for a three-layer neural network or Generalized Feed-forward Neural Network (GNN). Key features of the second embodiment are that it is easy to represent in the controller and fast to evaluate. Both the linear model and the neural network models exhibit these computational characteristics. The model for thermal performance is typically specified during die “burn-in” or initial manufacturing. It is possible to update this model dynamically, based on measurements by sensors contained in the solid-state memory system.

Continuing, after the first characteristic is estimated using the model from the performance model database, a comparison is made to the actual performance (step 405) and a “score” is given based on this comparison (step 407). For example, large deviations from the predicted performance will result in “low” scores, and vice versa.

In various embodiments, additional models may be used to estimate other performance characteristics such as current draw, read/write time, etc. The estimated performance characteristics for a plurality of models can be combined, using the weighting factors specified in the performance model database, to obtain an overall performance score for the candidate memory location. Thus, at step 409 additional parameters are measured and at step 411 these parameters are compared to predicted models. A score is determined (step 413) for each parameter, and a “total” score is assigned to the candidate memory location (step 415), based on a combination of all scores obtained, and used in the subsequent rank-ordering of the list of available memory locations for the given write operation.

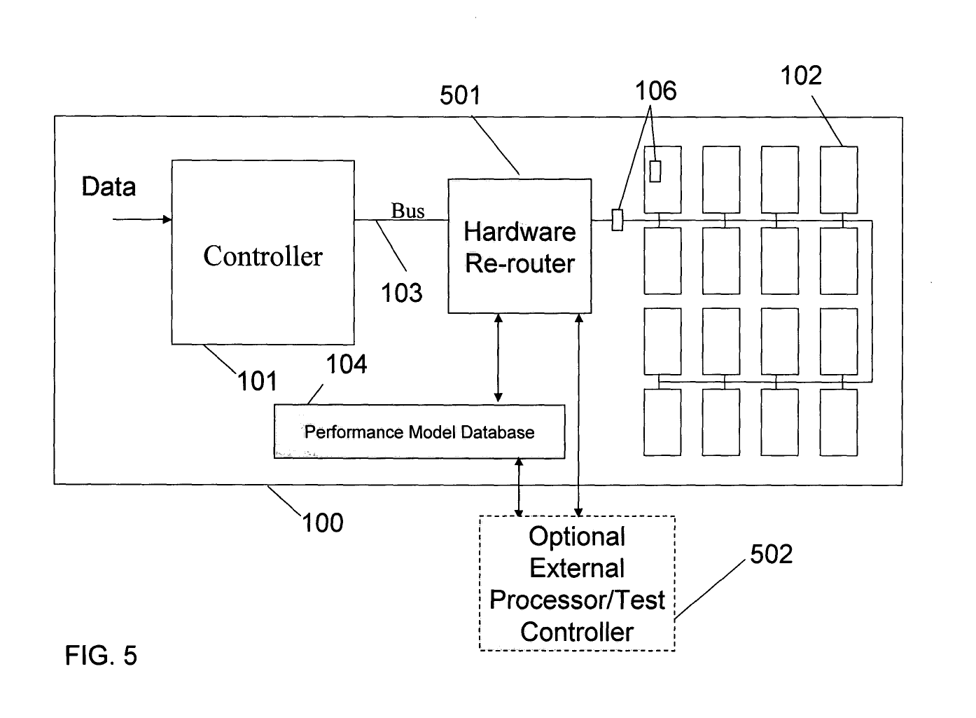

FIG. 5 is a block diagram of solid-state storage device 500 in accordance with an alternate embodiment of the present invention. As shown, device 500 is similar to device 100, except for the addition of hardware re-router 501 and optional external processor/test controller 502. In this embodiment, hardware re-router 501 is utilized to re-route the I/O bus lines in a manner which is transparent to controller 101. Particularly, controller 101 outputs data with a specific storage address that hardware re-router changes based on operating characteristics of the die. Optional external processor tester 502 is utilized to evaluate the conditions of die 102, and to program re-router 501 in order to optimize system performance based on these tests. In particular, tester 502 has current operating parameters for the plurality of memory die as an input along with historical operating parameters for the plurality of memory die. Tester 502 outputs storage locations to re-router 501, essentially configuring re-router 501. Processor 502 is used if controller 101 is unable to perform tests of die 102 and/or configure the re-router 501, or if it is undesirable for controller 101 to perform these functions.

Operation of device 500 occurs as follows: die 102 are tested by controller 502 to determine environmental parameters, for example, whether or not a die is functional. These tests may include a series of erase/write/read cycles, which evaluate whether each die are functioning properly. Alternatively to increase speed of test, the test can be simply a read of each die identification number (ID), where it is assumed that a non-functional die will return an invalid ID, or fail to respond to the request altogether. The tests may be performed by controller 101, but are preferably performed by an external test processor 502, which may be part of a test station used during product manufacture. Alternatively, the test processor 502 may be a controller available within the system, able to be utilized during a field re-configuration of re-router 501.

Information that can be used to identify good and bad die is stored in database 104, which preferably is some form of nonvolatile memory storage (e.g., NVM flash, EEPROM, ROM, etc.). Alternatively, database 104 may be accessed by controller 502 to determine historical performance and compare the historical performance to existing performance. In a preferred embodiment, re-router 501 transparently re-configures the arrangement of die array 102 by redirecting chip enable lines originating from controller 101. This configuration is based on either the testing alone, or a combination of the testing and comparison with historical values. Regardless of the method used for determining the best storage locations, re-router has the optimal storage locations as an input and re-routes data, based on the optimal storage locations. Thus, data exiting controller 101 will be destined for a first address and then re-routed to a second address by re-router 501 to achieve optimal performance.

Re-router 501 is programmed utilizing a method of volatile memory storage, which in some instances, may be necessary due to the stringent timing requirements of bus 103. Preferably, re-router 501 is based on D-type latch arrays, which are preprogrammed with the desired chip enable reconfiguration, with one array dedicated to each die in array 102. Each array is activated and tied to bus 103 when the corresponding chip enable line from controller 101 is activated, with the outputs of all other latch arrays disabled. In this configuration, the actual arrangement of memory die 102 is altered, depending on the functionality of each memory element 102 stored in database 104.

For example, if there are N number of die in array 102, it is assumed that there are N chip enable lines in bus 103 originating from controller 101. One chip enable is assigned to one die in array 102. Therefore, N×N latches are made available, and each array of N latches is programmed with one of N possible combinations of chip enables. To one skilled in the art, this configuration may appear redundant. Nevertheless, such use of arrays results in signal delay times, where sufficiently short timing is dependent on solely the delay in enabling/disabling tri-state buffered latch outputs, rather than latch programming time. This ensures that the operation of the re-router 501 is essentially transparent to the operation of controller 101.

In addition to removing non-functional die from service, database 104 may also allow for good die to be taken out of service in the event that operating conditions require it. For example, some die arrangements require two buses 103, each containing an identical number of die 102 connected to each bus. It is possible that during die test, one or more die will be determined to be non-functional, resulting in an unequal number of operational die connected to each of the two buses. In this case, database 104 may allow one or more die to be disabled by re-router 501 but marked as “good,” in the event that an additional die later fails, and a replacement is needed.

Finally, a large number of redundant die may by included in die array 102, where two die are simultaneously enabled by re-router 501 during write operations. In this configuration, data are written to two die instead of one, thereby creating a backup copy. This process is essentially transparent to the operation of controller 101. Typically during read accesses, a single die in the pair will be enabled. If this die fails, the backup die can be substituted by re-router 501, preventing the loss of data or interruption of service. The system then may alert a user or a host controller that a die had malfunctioned, which can be replaced at a convenient time.

While the invention has been particularly shown and described with reference to a particular embodiment, it will be understood by those skilled in the art that various changes in form and details may be made therein without departing from the spirit and scope of the invention. It is intended that such changes come within the scope of the following claims.

1. An apparatus comprising:
a first solid-state memory die;
a second solid-state memory die; and
a controller sensing one or more operating parameters for the first and the second solid-state memory die and making intelligent decisions on where to write data, based on the operating parameters.

2. The apparatus of claim 1 wherein the first and second solid-state memory die comprises flash memory, MRAM, SRAM, DRAM, FRAM, or polymer memory.

3. The apparatus of claim 1 wherein the operating parameters comprise temperature, current draw, or access time.

4. The apparatus of claim 1 further comprising a database storing known operating models for the first and the second die.

5. The apparatus of claim 1 further comprising a database storing known operating models for the first and the second solid-state memory die, and wherein the controller senses one or more operating parameters for the first and the second solid-state memory die and accesses the known operating models for the first and the second die and makes intelligent decisions on where to write data, based on the operating parameters and the known operating models.

6. The apparatus of claim 1 further comprising a File Access Table (FAT) storing available memory locations within the first and the second die.

7. An apparatus comprising:
a performance model database storing historical operating parameters for a plurality of memory die;
a processor/test controller having operating parameters for the plurality of memory die as an input and outputting optimal storage locations;
a controller having data as an input and outputting the data destined to be written to a first memory location; and
a hardware re-router having the optimal storage locations as an input along with the data, and re-routing the data, based on the optimal storage locations.

8. The apparatus of claim 7 wherein the memory die comprises memory taken from the group consisting of flash memory, MRAM, SRAM, DRAM, FRAM, and polymer memory.

9. The apparatus of claim 7 wherein the operating parameters comprise operating parameters taken from the group consisting of temperature, current draw, access times, and whether the memory die is functional.

10. A method for accessing a collection of one or more solid-state memory die, the method comprising the steps of:
retrieving operating parameters from the solid-state memory die;
retrieving operating models for the solid-state memory die;
comparing the operating models with the operating parameters;
determining a memory location to write data, based on the comparison; and
writing the data to the memory location.

11. The method of claim 10 further comprising the step of updating a file-access table (FAT) based on the step of writing the data to the memory location.

12. The method of claim 10 further comprising the step of:
updating the operating models based on the retrieved operating parameters.

13. The method of claim 10 wherein the step of retrieving operating parameters from the plurality of solid-state memory die comprises the step of retrieving operating parameters from a plurality of solid-sate memory device take from the group consisting of flash memory, MRAM, SRAM, DRAM, FRAM, and polymer memory.

14. The method of claim 10 wherein the step of retrieving operating parameters comprises the step of retrieving operating parameters taken from the group consisting of temperature, current draw, access times, and whether the die is functional.

15. The method of claim 10 wherein the step of retrieving operating models for the plurality of solid-state memory die comprises retrieving operating models from an internal database.
